(19) United States
(12) Patent Application Publication
(10) Pub. No.: US 2005/0227637 A1
(43) Pub. Date: Oct. 13, 2005

(54) Signal enhancement

(76) Inventor: Victor L Nendick, HAMPSHIRE (GB)

Correspondence Address: NIXON & VANDERHYE, PC, 901 NORTH GLEBE ROAD, 11TH FLOOR, ARLINGTON, VA, 22203, US

(21) Appl. No.: 10/513,158

(22) PCT Filed: Apr. 28, 2003
(86) PCT No.: PCT/GB03/01808

§ 371 Date: Nov. 2, 2004

(30) Foreign Application Priority Data
May 3, 2002 (GB) 0210159.0

(51) Int. Cl. H04B 17/00; H03C 1/62

(52) U.S. Cl. 455/115.1; 455/67.11

(57) ABSTRACT

An improved signal enhancing system/method providing a number of magneto-static wave propagation elements 30, 35 in the available reception and transmission paths, the propagation element(s) 30, 35 being particularly selected to be signal transmittable over a predetermined frequency range and power level. Signals are processed in a predetermined fashion and then passed through the selected propagation element(s), enabling the overall wanted signal to noise/interference level to be controllably enhanced. Conveniently, the signal enhancing system can utilise parallel and/or serial combinations of magneto-static wave enhancer devices to realise the desired technical effect if desired. The system bears definite advantage over known systems and retains utility for various signal enhancement applications, for example in satellite communications, communication terminals, modems and transponders.

### FIELD OF THE INVENTION

The present invention relates to a signal enhancing system and more particularly, but not exclusively, concerns an improved signal enhancing method and system using magneto-static wave (MSW) propagation to enhance signal link carrier to noise (C/N) ratio and carrier to interference (C/I) ratio, increasing overall communication capacity and achieving the same communication capacity with a smaller sized terminal (antenna/power).

### BACKGROUND OF THE INVENTION

Increases in communication capacity conventionally require increased transmitter radio frequency (RF) power and/or increased antenna size. Known signal enhancing systems typically rely upon the provision of a number of signal carriers leading to the generation of unwanted noise, spurii, in-band interference and intermodulation products (IMPS). Such known systems invariably have a large size, weight and high transmitter power, limiting the overall communication capacity and producing unwanted signal interference effects/signal degradation.

### OBJECTS AND SUMMARY OF THE INVENTION

The present invention aims to overcome or at least substantially reduce some of the above-mentioned drawbacks.

It is a principal object of the present invention to provide an improved signal enhancing system which can controllably enhance the overall wanted signal to noise/interference level, by means of controllably propagating signals through a magneto-static wave (MSW) device having selected transmission characteristics or through a combination of such magneto-static wave (MSW) devices.

It is another principal object of the present invention to provide an improved signal enhancing system which has the capability of substantially reducing noise, intermodulation products (IMPS) and spurious interference by taking advantage of signal tracking magneto-static wave (MSW) propagation in available reception/transmission paths.

In broad terms, the present invention resides in the concept of introducing a number of magneto-static wave (MSW) propagation paths, the propagation path(s) being selected to be signal transmittable over a predetermined frequency range and power level, and then passing signals which are processed in a predetermined fashion through the selected propagation path(s), enabling the overall wanted signal to noise/interference level to be controllably enhanced.

According to a first aspect of the present invention, there is provided a signal enhancing method in which one or more signals are generated and processed in a predetermined fashion and are subject to a number of magneto-static propagation paths, which number of magneto-static propagation paths are selected to be signal transmittable over a predetermined frequency range and power level, and wherein the one or more signals are selectively allowed to pass through said number of propagation paths enabling the resultant signal to noise/interference level to be controllably enhanced.

According to a second aspect of the present invention, there is provided a signal enhancing method comprising the steps of (a) generating and processing a signal at a first location in conventional fashion; (b) converting the signal so that the converted signal has (i) a first frequency characteristic within a predetermined frequency range and (ii) a predetermined amplitude characteristic; (c) providing a number of magneto-static propagation paths, the propagation path(s) being selected to have a signal transmission characteristic matched in accordance with the converted signal characteristic of (b); (d) passing the converted signal of (b) through said selected propagation path(s), enabling the overall signal to noise/interference level to be controllably enhanced; and (e) converting the resultant enhanced signal of (d) to provide a signal having a second frequency characteristic for subsequent processing at a second location.

According to a third aspect of the present invention, there is provided a signal enhancing system comprising: means for generating and processing a signal at a first location in conventional fashion; means for converting the signal so that the converted signal has (i) a first frequency characteristic within a predetermined frequency range and (ii) a predetermined amplitude characteristic; means for providing a number of magneto-static propagation paths, the propagation path(s) being selected to have a signal transmission characteristic matched in accordance with the converted signal characteristic; means for passing said converted signal through said selected propagation path(s), enabling the overall signal to noise/interference level to be controllably enhanced; and means for converting the resultant enhanced signal to provide a signal having a second frequency characteristic for subsequent processing at a second location.

In accordance with several embodiments of the invention which will be described hereinafter in detail, the signal enhancing system uses parallel and/or serial combinations of magneto-static wave enhancer devices to reduce noise, spurii and intermodulation products (IMPS) which would otherwise degrade the wanted signal(s). This could be achieved using various filters, various signal carriers, various signal power levels and/or various circuit gain combinations if desired.

Advantageously, there may be provided two magneto-static propagation paths in the system, one propagation path being used to suppress strong signal interference and the other propagation path being used to enhance controllably the overall wanted signal to noise/interference level.

Advantageously, there may be provided a magneto-static propagation path in combination with a conventional signal suppression circuit to control the levels of interference absorbed and reflected by the circuit, enabling an enhancement in the suppression of strong signal interference effects.

Advantageously, the proposed method/system of the invention provides an inventive way of increasing overall communication capacity without suffering from the drawbacks of increased size, weight and power associated with known methods/systems.

Conveniently, the reduction/minimisation of transmitter power in the method/system of the invention reduces the unwanted effects of spurii and interference and the likelihood of exploitation by collocated signal receivers.

Further, the method/system of the invention bears the advantage of effectively limiting strong signals within the magneto-static wave (MSW) propagation path(s), thereby reducing interference effects.

Further, the proposed form of magneto-static wave (MSW) propagation provides an effective mode of signal amplitude tracking to reduce/prevent signal degradation associated with conventional strong signal suppression devices (FISS), avoiding receiver paralysis or degradation.

Further, the inherent wide bandwidth of the proposed form of magneto-static wave (MSW) propagation is conveniently used to support (i) signal modulation and encoding techniques at both high and low data rates and (ii) voice transmission with or without compression techniques.

Advantageously, the system of the invention can be configured to provide a reduction of terminal size, weight and power without adversely affecting its overall communications capacity.

Advantageously, the system of the invention can be configured to provide a reduction of transmitter power and collocated receiver interference without reducing overall communications capacity.

Advantageously, broadband noise emissions can be reduced in the system without reducing overall communications capacity.

Advantageously, the system of the invention can be configured to permit the removal of intermodulation products (IMPS) within the available transmission and reception paths of multiple high level signal carriers for example, with small or large frequency separations.

Advantageously, the system of the invention can be configured to reduce noise, spurii and interference effects arising in look-through transmissions and in quiescent periods for example, enhancing signal reception and signal interleaving.

Advantageously, signal transmissions in the system can be in the form of continuous wave (CW), pulse, or burst mode using single/multiple carriers so as to reduce the unwanted effects of noise, spurii and intermodulation products (IMPS). It is to be noted that the signals can be conveniently modulated using current established modulation techniques, FHSS, DSCS, QPSK, BPSK for example.

Conveniently, it is possible to use the system of the invention to reduce the unwanted effects of noise, spurii and intermodulation products in direct or indirect transmission/reception paths (indirect transmission paths through a transparent transponder, for example).

Conveniently, the system of the invention has the capability of reducing the unwanted effects of noise, spurii and intermodulation products in wide, narrow, and near zero circuit bandwidths, and in the so called “in-band” frequency range which conventional systems cannot do without reducing the wanted signal(s) level. It is to be noted that the “in-band” frequency range is defined to be the frequency bandwidth of the wanted signal(s).

Conveniently, it is possible to use the system of the invention to reduce noise, spurii and intermodulation of spread spectrum carriers before or after despreading of the carriers.

Having regard to the foregoing, the signal enhancing system of the invention has better performance over known systems insofar as it can significantly enhance the wanted signal to noise/interference level without need for conventional strong signal suppression devices.

It is to be appreciated that the signal enhancing system of the invention finds utility in various communication applications, for example in satellite communications, communication terminals, modems and transponders.

It is also to be appreciated that the present invention extends to any system adapted and arranged to carry out the above described signal enhancing method.

The above and further features of the invention are set forth with particularity in the appended claims and will be described hereinafter with reference to the accompanying drawings.

### BRIEF DESCRIPTION OF THE DRAWINGS

FIG. 1 is a block schematic of a conventional signal communications system with reception and transmission paths;

FIG. 2 is a block schematic of a signal enhancing system embodying the present invention;

FIG. 3 is a block schematic of a signal enhancing system embodying the present invention for deployment with multiple carriers or groups of carriers;

FIG. 4 is a block schematic of a cascaded magneto-static propagation arrangement of the present invention;

FIG. 5 is a block schematic of a strong signal suppression circuit for application in the system of the present invention; and

FIGS. 6 to 8 show typical signal propagation enhancement characteristics of a signal enhancing system embodying the present invention.

### DETAILED DESCRIPTION OF EXEMPLARY EMBODIMENTS

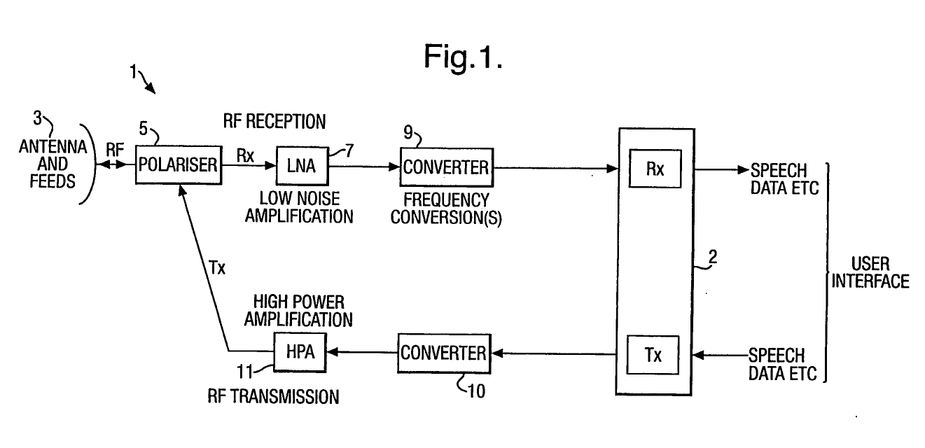

Referring first to FIG. 1, there is schematically shown a conventional signal communications system 1 having available reception and transmission paths.

As shown in FIG. 1, the signal reception path defined in relation to the user interface end 2 is typically provided by energising (i) an antenna 3 with feeds to generate a radio frequency (RF) signal, (ii) polarising the (RF) signal with a polariser 5, (iii) power amplifying the polarised signal using a low noise amplifier 7, and (iv) frequency converting 9 and demodulating the resultant signal using a mixer and modem, thereby enabling carriers to be demodulated into baseband format for reception and processing at the user interface end 2.

Further, as shown in FIG. 1, the signal transmission path defined in relation to the user interface end 2 is typically provided by (i) first generating a signal, a speech data signal for example, at the user interface end 2, (ii) frequency converting 10 the resultant signals using a mixer and modem, (iii) power amplifying the converted signal using a high power amplifier 11, and then (iv) polarising 5 the amplified signal prior to its reception by an antenna 3.

In operation of the thus described system 1 of FIG. 1, however, the wanted signal level is typically degraded/contaminated to a high degree by the generation of noise, spurii, in-band interference and intermodulation products (IMPS).

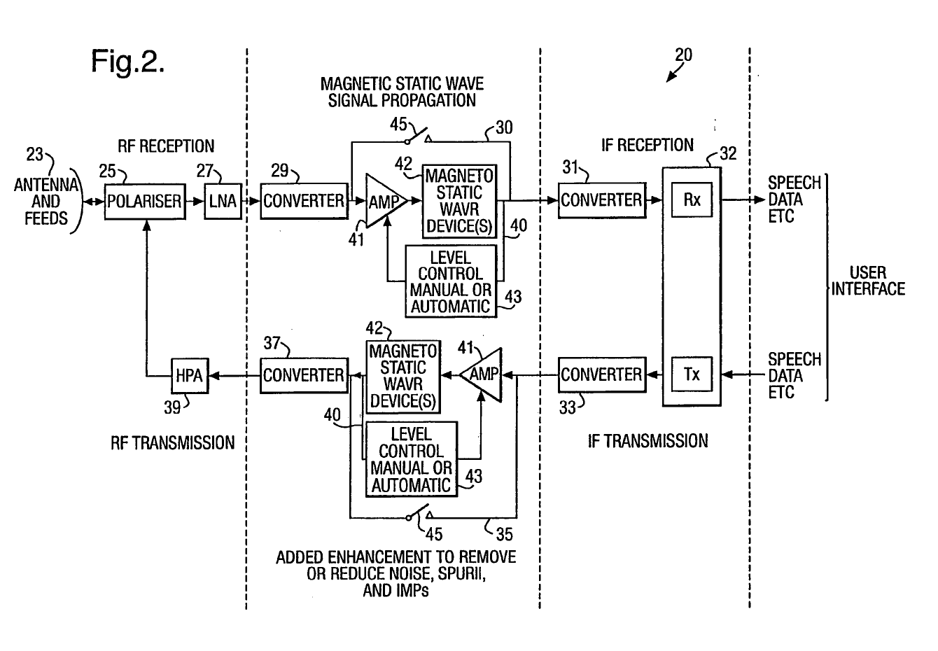

Referring next to FIG. 2, there is schematically shown a preferred signal enhancing system 20 embodying the present invention. As shown, the signal enhancing system comprises the standard elements of FIG. 1, and a number of magneto-static propagation elements which are inventively incorporated into the available reception/transmission communicating paths, permitting noise, spurii and intermodulation products (IMPS) arising in the system to be removed/reduced.

As shown in FIG. 2, the signal reception path in the system 20 is provided by (a) energising an antenna 23 with feeds to generate a radio frequency (RF) signal, (b) polarising the RF signal with a polariser 25, (c) power amplifying the polarised signal to a predetermined power level using a low noise amplifier (LNA) 27, (d) shifting down by a predetermined amount the frequency band of the power amplified signal using a frequency converter/mixer 29, (e) subjecting the converted signal to a controlled signal level enhancement via a first selected magneto-static wave (MSW) propagation element 30, (f) shifting down by another predetermined amount the frequency band of the resultant enhanced signal using another frequency converter/mixer 31 and (g) demodulating the signal into baseband format for the purpose of subsequent signal processing at the user interface end 32.

As also shown in FIG. 2, the signal transmission path in the system 20 is provided by (a) generating and transmitting a data signal having a predetermined power level at the user interface end 32, (b) shifting up by a predetermined amount the frequency band of the transmitted signal using a frequency converter/mixer 33 and modem, (c) subjecting the converted signal to controlled signal level enhancement via a second selected magneto-static wave (MSW) propagation element 35, (d) shifting up by another predetermined amount the frequency band of the resultant enhanced signal using a frequency converter/mixer 37, (e) power amplifying the signal using a high power amplifier (HPA) 39, and (f) polarising the amplified signal with a polariser 25 for subsequent reception by an antenna 23.

Conveniently, as shown, the first and second magneto-static wave propagation elements 30, 35 each comprise feedback circuitry 40 including (i) an amplifier element 41 for receiving at its input the converted signal from converter 29, 33, (ii) a magneto-static wave enhancer device 42 which receives the amplified output, and (iii) signal control means 43 for controllably feeding back the enhanced device output to the amplifier input. It is also to be understood that the feedback circuitry 40 is preferably controllably activated by actuation of switch means in a by-pass circuit route 45, the route 45 being connected to the input of the amplifier element at one end and to the enhancer device output at its other end. The provision of such a by-pass circuit route 45 allows an operator to control/optimise the wanted signal quality in a flexible manner.

Preferably, as shown, the signal control means 43 is in the form of a standard manual or automatic signal level control, enabling an operator to control/optimise the signal carrier to noise (C/N) ratio and signal carrier to interference (C/I) ratio if desired.

Conveniently, the magneto-static wave enhancer devices 42 of FIG. 2 can operate in wide circuit bandwidths, in narrow and near zero circuit bandwidths and in the “in-band” frequency range corresponding to the frequency range of the wanted signals(s). It is to be appreciated that the magneto-static wave enhancer devices 42 are particularly selected and provided in the system 20 to (i) pass signals with a predetermined power level and predetermined frequency range and (ii) strongly suppress extraneous signal levels which are characterised by power levels and/or frequency ranges which fall outside the predetermined MSW power level/frequency band characteristic.

Preferably, each MSW enhancer device 42 is formed of Gadolinium Gallium Garnet substrate material.

Further, each MSW enhancer device 42 can operate in circuit bandwidths capable of passing continuous wave (CW), pulse, or burst modulated or unmodulated carriers. It is to be noted that each device, in operation, is placed in a suitably strong magnetic field orientated such as to provide/maximise signal carrier enhancement.

The MSW enhancer devices 42 of the thus described arrangement 20 of FIG. 2, therefore, operate in a controlled manner to control/optimise the overall C/I and C/N enhancement at the predetermined (optimum) MSW power level/frequency band. For example, the MSW propagation paths can be typically selected such as to be signal transmittable over a 0.5 GHz to 1 GHz frequency bandwidth. The transmitted signal power level is typically 20 mW.

In operation of the thus described system 20, it will be understood that different numbers of magneto-static propagation elements (i.e. one, two or more elements) can be readily incorporated into the system and that it is possible for example to provide a parallel cascading arrangement or a serial cascading arrangement of MSW propagation elements for enhancing/optimising system performance for each signal carrier or group of carriers. This type of cascaded arrangement is to be described hereinafter.

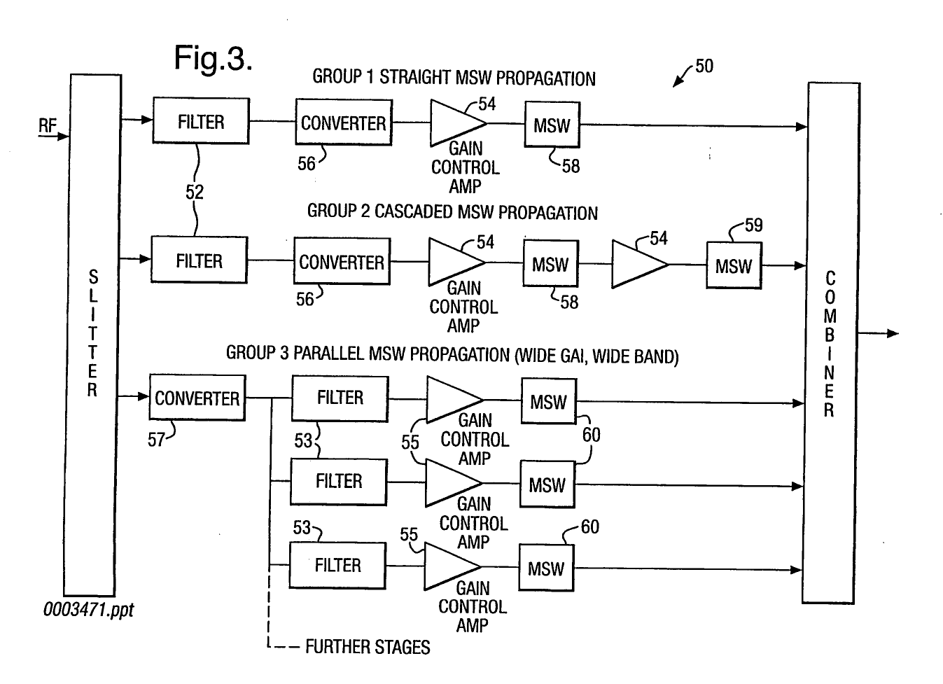

FIG. 3 is a simplified block schematic of another signal enhancing system 50 embodying the present invention which is particularly suitable for deployment with multiple signal carriers or groups of carriers for enhancing carrier to noise (C/N) and/or carrier to interference (C/I) ratio.

More particularly, as shown in the Figure, magneto-static wave (MSW) propagation of multiple carriers or carrier groups is carried out in the system 50 using filters 52, 53, gain control amplifiers 54, 55, and various cascaded parallel and serial combinations of filters 52, 53, amplifiers 54, 55, converters 56, 57, and MSW enhancer devices 58, 89, 60. Groups of carriers of similar amplitude/power and frequency are conveniently treated individually by the shown elements in turn, and the net overall effect is to enhance/optimise the carrier to noise (C/N) ratio and/or the carrier to interference (C/I) ratio by virtue of effectively varying the signal power and frequency to match that of the selected MSW propagator.

Since the MSW propagation serves to enhance C/N and/or C/I over a relatively wide frequency band it is often not necessary to use such combinations of elements to achieve the desired technical effect of the invention. Nonetheless, it is to be appreciated that this type of arrangement 50 could be used if desired.

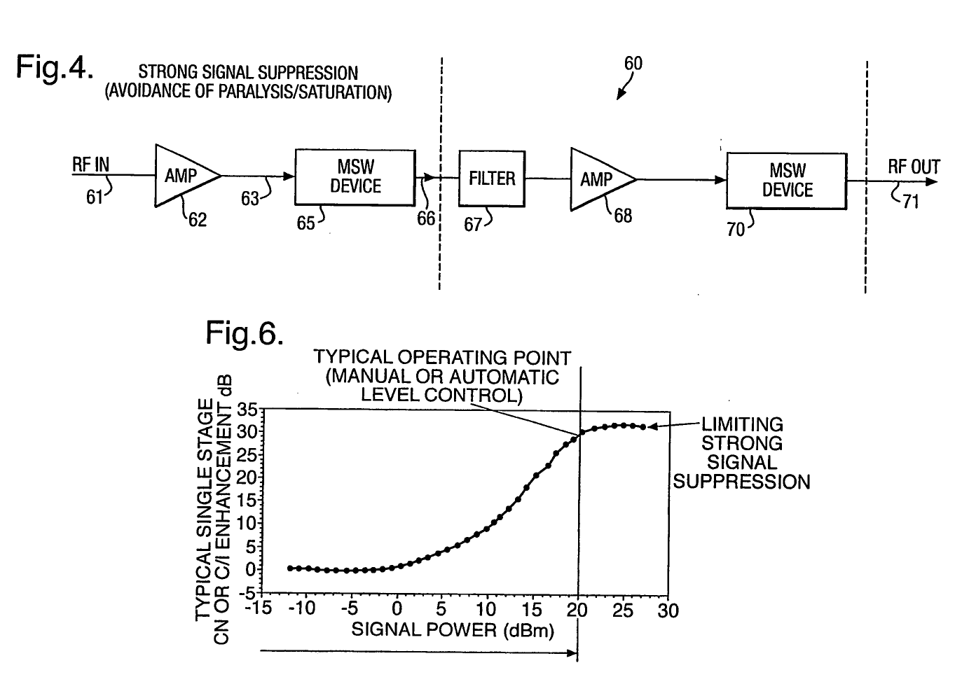

FIG. 4 is a simplified block schematic of a cascaded magneto-static propagation arrangement 60 of the invention.

As shown in the Figure, an incident RF signal 61 is first fed into a gain control amplifier 62 and the amplified output 63 is then passed through a first magneto-static wave (MSW) enhancer device 65. The first MSW enhancer device 65 is orientated in relation to the applied magnetic field in such a way as to enhance/maximise strong signal interference suppression. The result of this action is to provide a refined transmitted signal 66, free of strong signal interference effects. As shown, the resultant signal is then passed through (i) a filter 67 to remove residual interference effects, (ii) a gain control amplifier 68 and (iii) a second magneto-static wave (MSW) enhancer device 70 prior to processing/treatment of the enhanced output 71 (RF OUT) at a user interface (not shown) for example. Thus, the net effect of the second MSW enhancer device 70 is to enhance/maximise the wanted signal to noise/interference level, enabling a better signal quality processing at the enhanced output end.

Advantageously, the system 60 of FIG. 4 addresses the technical problem of how to avoid front-end paralysis or saturation which could otherwise severely degrade the overall C/I and/or C/N enhancement level.

It is to be understood that a different number of cascaded MSW propagation paths can be effectively incorporated into the system whereupon at least one propagation path is used to reduce/limit strong interference and a second or more propagation path is used to enhance/optimise the overall C/N and/or C/I enhancement level.

It is further noted that conventional filters where practicable can be used in the system 60 without degrading the system's C/N and C/I.

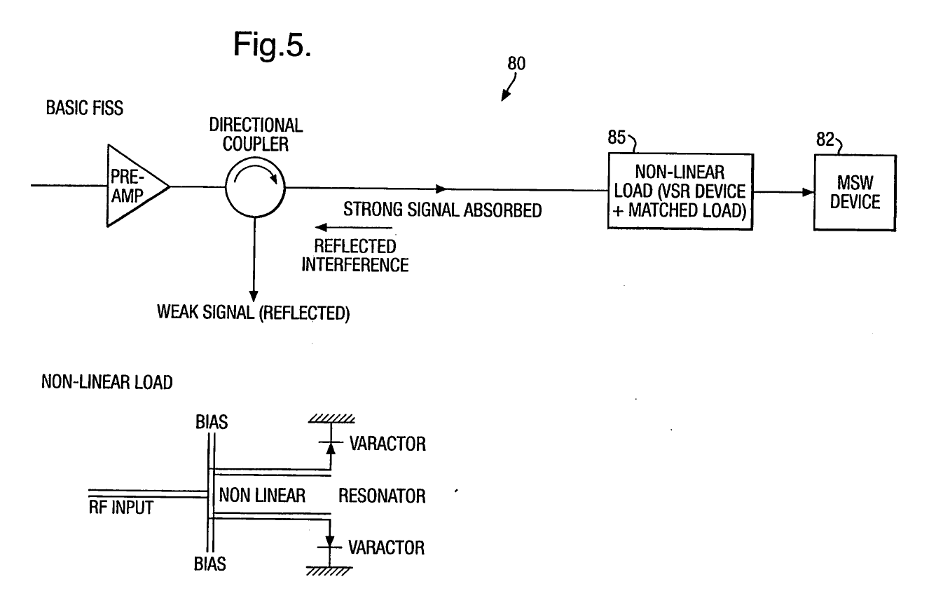

FIG. 5 is a simplified block schematic showing how a strong signal suppression circuit 80 is applied to the system of the invention.

It is known that indirect strong signal interference suppression can be achieved by means of frequency independent strong signal suppression (FISSS) devices/circuits similar to the circuit 80 shown in FIG. 5. The inventor has found that the introduction of a MSW propagation path 82 to such a circuit 80 surprisingly enhances the interference suppression capability by cancellation/reduction of the reflected interference (IMPS and noise) from the non-linear load 85. The MSW propagation path 82 additionally provides a means of interference envelope tracking to permit control of the critical DC bias, as supplied to the shown FISSS non-linear load, using the non-linear gain characteristic of a dedicated/common MSW device to optimise the bias correction. This arrangement, thus, conveniently provides a highly selective and effective mode of strong signal interference suppression for variable interference signal levels.

It is also to be appreciated that the selected MSW propagation path can be used with other kinds of load/known element to achieve the desired technical effect of the invention.

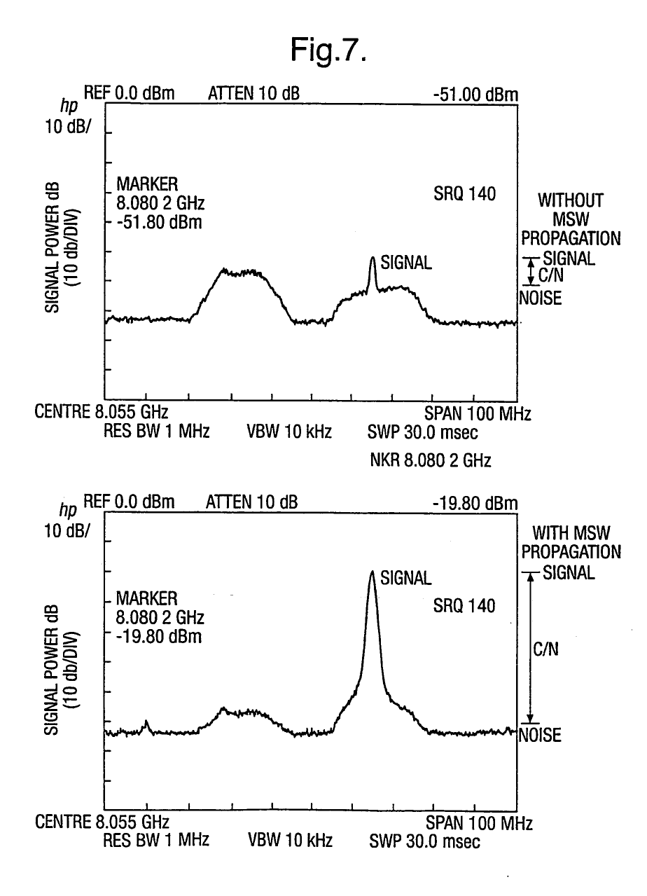

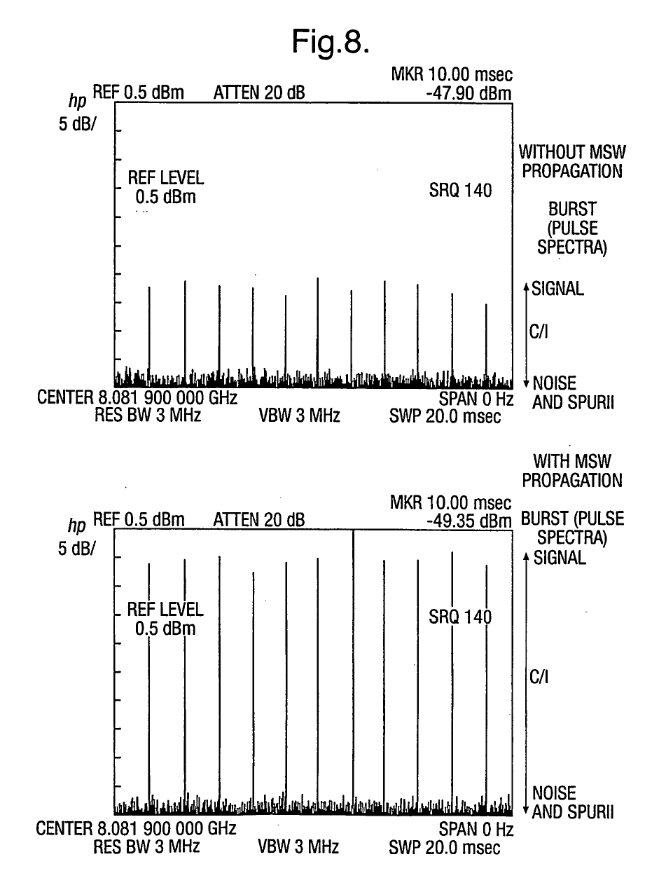

By way of example, FIGS. 6 to 8 show typical signal propagation enhancement characteristics of a signal enhancing system embodying the invention. For sake of comparison, typical signal enhancement characteristics of a conventional system are also provided in FIGS. 7 and 8.

FIG. 6 shows how the overall C/N or C/I enhancement level progressively increases in the inventive system, typically, as the input signal (RF) power to the selected MSW enhancer device is allowed to increase over the range 0 to 25 dBm. Note that the overall signal to noise/interference enhancement level typically reaches a saturation level at around 32 dB corresponding to an input signal power of around 25 dBm.

FIGS. 7 and 8 illustrate the improvements in signal to noise/interference ratio as provided by the inventive system, compared to that in conventional systems (where no MSW propagation path is used).

For example, in FIG. 7, the C/N ratio as provided by the inventive system with MSW propagation is about five times better than that of a typical conventional (without MSW propagation) system.

In FIG. 8, the C/I ratio for low duty cycle burst (pulse) signal transmissions as provided by the inventive system is shown to be at least two times better than that of a typical conventional system.

The above described definite visible improvements in signal quality over that in conventional systems (where no MSW propagation path is used), as shown in FIGS. 6 to 8, are directly attributed to the introduction of one or more MSW propagation paths within the available transmission and reception paths of the inventive system.

Having regard to the foregoing, it is noted that the inventive use of a number of MSW propagation paths within available (RF) transmission and reception paths for the purpose of reducing noise, spurii, IMPS and interference in the system finds particular, but not exclusive, application to the following situations:
(a) Enhance C/N and/or C/I, whilst reduce communications equipment size, weight and/or increase their traffic capacity;
(b) Burst mode transmissions for ESM, TDMA for example by reduction of quiescent noise (facilitating user interleaving);
(c) Enhance loop through transmission by reduction of quiescent noise;
(d) Enhance transponder capacity and power initialisation by reduction of coupled noise, IMPs and spurii;
(e) Reduce broad and narrow band interference to co-located receivers by reduction of broadband noise, IMPs and spurii; and
(f) Enhance the RF front end performance of modems by reduction of noise, IMPs and spurii (before and/or after signal despreading).

Therefore, as previously described, the signal enhancing method of the invention puts the following key steps into effect:
(a) generating and processing a signal at a first location in conventional fashion;
(b) converting the signal so that the converted signal has (i) a first frequency characteristic within a predetermined frequency range and (ii) a predetermined amplitude characteristic;
(c) providing a number of magneto-static propagation paths, the propagation path(s) being selected to have a signal transmission characteristic matched in accordance with the converted signal characteristic of (b);
(d) passing the converted signal of (b) through said selected propagation path(s), enabling the overall signal to noise/interference level to be controllably enhanced; and
(e) converting the resultant enhanced signal of (d) to provide a signal having a second frequency characteristic for subsequent processing at a second location.

Note that the first location here could correspond to the location of a front terminal end and the second location could correspond to the location of a user terminal end/user interface for example.

Having thus described the present invention by reference to various embodiments, it is to be well understood that the embodiments in question are exemplary only and that modifications and variations as will occur to those possessed of the appropriate knowledge and skills may be made without departure from the spirit and scope of the invention as set forth in the appended claims and equivalents thereof. For example, various numbers of MSW propagation paths can be selectively introduced into the system of the invention to provide the desired technical effect. In this connection, various MSW propagation paths (at least two paths) can be effectively utilised in cascaded parallel or serial combinations, enabling the signal to noise/interference level to be controllably enhanced. Further, the MSW enhance device(s) of the system can effectively operate in wide, narrow and near zero circuit bandwidths. Further, various kinds of signal having different shapes/waveforms, amplitudes and/or bandwidths can be received and effectively enhanced by the system of the invention. Further, whilst in one of the described embodiments a MSW propagation path is selectively introduced and combined with a conventional signal suppression circuit including a non-linear load (VSR device and matched load), it is to be noted that the number of MSW propagation paths could be easily varied and that other kinds of conventional load/element could be used in place of the described load if desired.

Further, whilst in another described embodiment the MSW propagation path(s) are provided by feedback circuitry, it is to be noted that this kind of arrangement is not necessary and that it is necessary only to provide a selected MSW propagation path in the system with the desired frequency bandwidth and desired power level characteristic so as to realise the desired inventive technical effect. Typically, the desired frequency bandwidth is between 0.5 GHz and 1 GHz and the desired power level is typically 20 mW.

It is to be appreciated that the system of the present invention finds utility in various signal communication applications, for example in satellite communications, communication terminals, modems and transponders.

1. A signal enhancing method comprising the steps of:
(a) generating and processing a signal at a first location in conventional fashion;
(b) converting the signal so that the converted signal has (i) a first frequency characteristic within a predetermined frequency range and (ii) a predetermined amplitude characteristic;
(c) providing a number of magneto-static propagation paths, the propagation path(s) being selected to have a signal transmission characteristic matched in accordance with the converted signal characteristic of (b);
(d) passing the converted signal of (b) through said selected propagation path(s), enabling the overall signal to noise/interference level to be controllably enhanced; and
(e) converting the resultant enhanced signal of (d) to provide a signal having a second frequency characteristic for subsequent processing at a second location, characterised in that two magneto-static propagation paths are provided and said paths are provided by means of a serial cascading arrangement of magneto-static wave enhancer devices.

2. A method of enhancing received and generated signals comprising the steps of: selectively subjecting the signals to at least one magneto-static propagation path, said at least one magneto-static propagation path being adapted to support signals of a predetermined frequency range and power level; allowing the signals to pass through said at least one propagation path, thereby enabling the resultant signal-to-noise level and/or signal-to-interference level to be controllably enhanced; characterised in that:
in a receiving mode, a polarised signal is received for selective input to at least one magneto-static wave device (42), said at least one device (42) being adapted to convert the signal to a magneto-static wave by way of feedback circuitry (40); an enhancing device (43), including an amplifier (41), which receives the converted signal and outputs an enhanced output signal, with reduced signal-to-noise and/or signal to interference level; the enhanced output signal is then controllably fed back to an amplifier (41) whose output is fed to the magneto-static wave device (42);
and in a transmission mode, generating an output signal for transmission, said output signal having a predetermined power level; shifting the frequency of the output signal to a predetermined frequency band using a first frequency converter/mixer (33), subjecting the output signal to controlled signal level enhancement using at least one magneto-static wave device (42), said at least one device (42) being adapted to convert the signal to a magneto-static wave by way of feedback circuitry (40), an enhancing device (43), including an amplifier (41), which receives the enhanced converted signal at its input and outputs an enhanced output signal, with reduced signal-to-noise and/or signal to interference level; the enhanced output signal is then controllably fed back to amplifier (41) whose output is fed to the magneto-static wave device (42); shifting the frequency band of the resultant enhanced signal using a second frequency converter/mixer (37), so as to controllably enhance the output signal; amplifying the output signal using a power amplifier (39); and polarising the amplified output signal for subsequent transmission by an antenna (23).

3. A method as claimed in claim 1, wherein two magneto-static propagation paths are provided enabling (i) strong signal interference to be suppressed using one of said paths and (ii) the signal to noise/interference level to be enhanced using the other of said paths.

4. A method as claimed in claim 1, wherein one of said magneto-static propagation paths is selectively combined with a conventional signal suppression circuit to control the levels of interference absorbed and reflected by the circuit, enabling the suppression of strong signal interference to be controllably enhanced.

5. A method as claimed in claim 1, wherein the quality of the signals is further enhanced by means of manual or automatic power level control.

6. A method as claimed in claim 1, wherein the signals are generated in radio-frequency continuous wave, pulse or burst mode using single or multiple carriers.

7. A method as claimed in claim 1, wherein the magneto-static propagation paths are selected to be over a 0.5 GHz-1 GHz frequency bandwidth.

8. A signal enhancing system adapted and arranged to carry out a method as claimed in claim 1.

9. A signal enhancing system for receiving and generating signals comprising:
at least one magneto-static propagation path, said at least one magneto-static propagation path being adapted to support signals of a predetermined frequency range and power level; allowing the signals to pass through said at least one propagation path, thereby enabling the resultant signal-to-noise level and/or signal-to-interference level to be controllably enhanced; characterised in that:
in a receiving mode there is a receiver having a polariser arranged to selectively input a signal to at least one magneto-static wave device (42), said at least one device (42) being adapted to convert the signal to a magneto-static wave by way of feedback circuitry (40); an enhancing device (43), including an amplifier (41), which receives the converted signal and outputs an enhanced output signal, with reduced signal-to-noise and/or signal to interference level; the enhanced output signal is fed back to an amplifier (41) whose output is fed to the magneto-static wave device (42);
and in a transmission mode, means is provided for generating an output signal for transmission, said output signal having a predetermined power level; a first frequency converter/mixer (33) shifts the frequency of the output signal to a predetermined frequency band, said output signal is subjected to controlled signal level enhancement using at least one magneto-static wave device (42), said at least one device (42) being adapted to convert the signal to a magneto-static wave by way of feedback circuitry (40); an enhancing device (43), includes an amplifier (41), which receives the enhanced converted signal at its input and outputs an enhanced output signal, with reduced signal-to-noise and/or signal to interference level; the enhanced output signal is then controllably fed back to amplifier (41) whose output is fed to the magneto-static wave device (42); a second frequency converter/mixer (37) for shifting the frequency band of the resultant enhanced signal to controllably enhance the output signal; a power amplifier (39) for amplifying the output signal and a polariser for polarising the amplified output signal for subsequent transmission by an antenna (23).

10. A signal enhancing system as claimed in claim 8, wherein said means for providing the propagation path(s) comprises a magneto-static wave enhancer device or a combination of magneto-static wave enhancer devices.

11. A signal enhancing system as claimed in claim 8 incorporating a Gadolinium Gallium Garnet substrate device.

12. A signal enhancing system as claimed in claim 8 or 10, wherein the first location corresponds to the location of a front terminal end and the second location corresponds to the location of a user interface end for signal communications.

13. A satellite communication system incorporating a signal enhancing system as claimed in claim 8.

14. (canceled)
